(19) United States
(12) Patent Application Publication
(10) Pub. No.: US 2025/0194064 A1
(43) Pub. Date: Jun. 12, 2025

(54) Shielding Plate for an Assembly of a Power Electronics Module With a Supporting Function

(71) Applicant: Bayerische Motoren Werke Aktiengesellschaft, Muenchen (DE)

(72) Inventors: Erick Maximiliano HAAS RUGEL, Muenchen (DE); Roman HAMERSKI, Unterhaching (DE); Maximilian HERRNBERGER, Oberhaching (DE); Roland LICHTINGER, Landau an der Isar (DE); Christian STEINLE, Muenchen (DE)

(21) Appl. No.: 18/843,366

(22) PCT Filed: May 22, 2023
(86) PCT No.: PCT/EP2023/063638

§ 371 Date: Sep. 3, 2024

(30) Foreign Application Priority Data
May 30, 2022 (DE) 10 2022 113 505.5

(51) Int. Cl. H05K 9/00; H01G 2/10; H01G 2/22; H01G 4/33

(52) U.S. Cl. CPC H05K 9/0081; H01G 2/103; H01G 2/22; H01G 4/33

(57) ABSTRACT

An assembly for a power electronics module of a motor vehicle, includes: a first component with at least one first, interference signal-emitting electrical component and an electrically insulating layer that covers the at least one first component; a second, interference signal-sensitive component; a shielding plate that is arranged between the first component and the second component for shielding the second component from the interference signals of the first component and is designed as a profiled plate with a raised region having at least one raised bead and with a recessed region having at least one recessed bead. The at least one recessed bead is mechanically connected to the electrically insulating layer of the first component in order to mechanically connect the shielding plate to the first component. The at least one raised bead forms a supporting region for the second component. The second component bears against and is fastened to the supporting region at least in certain areas.

### BACKGROUND AND SUMMARY

The invention relates to an assembly for a power electronics module of a motor vehicle. The assembly comprises a first component having at least one interference signal-emitting first electrical component part and having an electrically insulating layer covering the at least one first component part. In addition, the assembly comprises an interference signal-sensitive second component. Furthermore, the assembly comprises a shielding plate, arranged between the first and the second component, for shielding the second component from the interference signals of the first component. The invention additionally relates to a power electronics module for a motor vehicle.

In the present case, interest is focused on power electronics modules for motor vehicles. Such power electronics modules are, for example, inverters for electrically drivable motor vehicles, thus electric or hybrid vehicles. In this case, the inverter is connected between a high-voltage energy storage device and an electric machine of the motor vehicle and typically converts a high-voltage DC voltage provided by the high-voltage energy storage device into a multiphase AC voltage for operating the electric machine. In particular high-voltage-conducting components, i.e. high-voltage components, of the power electronics modules are generally enclosed by shielding plates, for example shielding sheets, in order to prevent interference signals of the high-voltage components from having a negative influence on other components of the power electronics module, such as signal paths of low-voltage components. This shielding is particularly relevant in the case of intermediate circuit capacitors, filter stages, and current sensors. A special challenge in this case is to place the interference signal-emitting components, the interference signal-sensitive components, and the shielding plates in a secure and space-saving manner in relation to one another.

It is the object of the present invention to provide a particularly cost-effective, component-saving, and space-saving arrangement of an interference signal-emitting component, an interference signal-sensitive component, and a shielding plate of a power electronics module for a motor vehicle.

This object is achieved according to the invention by an assembly and a power electronics module having the features according to the respective independent claims. Advantageous embodiments of the invention are the subject matter of the dependent claims, the description, and the figure.

An assembly according to the invention for a power electronics module of a motor vehicle comprises a first component having at least one first interference signal-emitting electrical component and an electrically insulating layer covering the at least one first component part. In addition, the assembly comprises a second interference signal-sensitive component. Moreover, the assembly comprises a shielding plate, arranged between the first and the second component, for shielding the second component from the interference signals of the first component. The shielding plate is designed as a profiled plate having a raised area comprising at least one raised bead and a depressed area comprising at least one depressed bead, wherein the at least one depressed bead is mechanically connected to the electrically insulating layer of the first component for the mechanical connection of the shielding plate to the first component and wherein the at least one raised bead forms a support area for the second component, on which the second component abuts at least in some areas or points and is fastened.

The invention additionally relates to a power electronics module for a motor vehicle having at least one assembly according to the invention. The power electronics module is in particular an inverter for an electric drive unit of the motor vehicle. The assembly comprises the two components, wherein the first component is in particular a high-voltage component and the second component is in particular a low-voltage component. The at least one first electrical component part of the first component is covered here by an electrically insulating layer. The first component is in particular an intermediate circuit capacitor for the inverter, wherein the at least one first component part is designed as an electrical capacitor, in particular a film capacitor. The first component can also be a filter stage.

The first component emits interference signals here, to which the second component is sensitive and which can thus interfere with operation of the second component. The second component is in particular designed as a control unit and comprises at least one signal path, which is arranged on a printed circuit board of the second component. In addition, further component parts can be arranged on the printed circuit board, such as control elements and sensor elements.

In order to be able to position the first and second component spatially close to one another in spite of the interference signals and join them together to form the assembly, the shielding plate is arranged between the first and the second component. In an arranged state of the assembly in the motor vehicle, the first component, the shielding plate, and the second component are in particular arranged one above another or stacked in the vertical direction. The shielding plate is designed here as a metallic EMC shielding plate and comprises, for example, an aluminum or steel alloy. The shielding plate is designed as multifunctional and, in addition to the shielding function, provides a supporting function or carrying function for the second component. For this purpose, the shielding plate is designed as a profiled plate and comprises the raised area and the depressed area. The depressed area is mechanically connected here to the electrically insulating layer of the first component, in particular at least partially integrated in the electrically insulating layer of the first component, and is therefore arranged particularly spatially close to, but electrically insulated from the at least one first electrical component part.

For example, the first component can comprise a housing open on one side, in which the at least one first electrical component part is arranged and which is covered by the electrically insulating layer. The electrically insulating layer is preferably formed by a potting compound, by which the at least one first component part is at least partially covered and in which the at least one depressed bead is embedded. For example, the housing can be filled with the potting compound so that the at least one first component part is embedded in the potting compound and the profiled plate dips in some areas into the potting compound. The profiled plate is thus materially bonded to the first component. In particular, the depressed area comprises a lattice structure for improving the mechanical connection between the electrically insulating layer and the profiled plate. Due to the lattice structure, the potting compound can completely surround the depressed area at multiple points, so that a secure mechanical connection can be established. In addition, interference noises, as can occur, for example, with a screwed-on shielding plate during a journey of the motor vehicle and a movement of the assembly resulting therefrom, are at least reduced by the embedding in some areas of the metallic shielding plate in the potting compound.

The second component is arranged at the raised area. An upper side of the at least one raised bead forms a support surface for the second component, for example the printed circuit board of the control unit. The support surface provided by the at least one raised bead is in particular smaller than an area of the second component. The second component abuts this support surface and is in particular thus only supported at some points. To fasten the second component on the at least one raised bead, it can be firmly adhesively bonded on the support surface. Since the metallic shielding plate can be adhesively bonded well, the second component can thus be fastened easily and securely on the shielding plate. A stable and space-saving assembly can thus be formed. Because the shielding plate functions as the carrier of the second component, additional supports can be omitted, so that the assembly can moreover be designed in a particularly part-saving and therefore cost-effective manner.

It has proven to be advantageous if the profiled plate is formed by deep drawing and at least the at least one raised bead is formed as a hollow body open on one side in the direction of the electrically insulating layer. In particular, the raised beads are formed by deep-drawn areas of the shielding plate at some points, which form the fastening points for the second component. A shape of the raised beads and an arrangement of the raised beads can be designed arbitrarily here.

The embodiments presented with reference to the assembly according to the invention and the advantages thereof apply accordingly to the power electronics module according to the invention.

Further features of the invention result from the claims, the figure, and the description of the figure. The features and combinations of features mentioned above in the description and the features and combinations of features mentioned hereinafter in the description of the figure and/or shown solely in the figure are usable not only in the respective specified combination, but also in other combinations or alone.

The invention will now be explained in more detail on the basis of a preferred exemplary embodiment and with reference to the drawing.

### BRIEF DESCRIPTION OF THE DRAWING

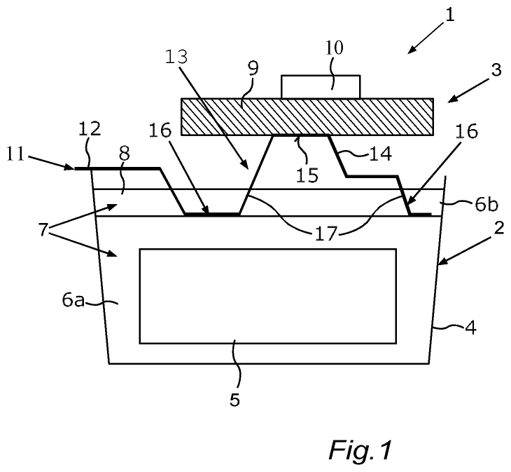

The single figure, FIG. 1, is a schematic representation of an embodiment of an assembly for a power electronics module of a motor vehicle.

### DETAILED DESCRIPTION OF THE DRAWING

Referring to the figure, an assembly 1 comprises a first component 2, for example an intermediate circuit capacitor, and a second component 3, for example a control unit or a sensor unit. The first component 2 comprises a housing 4, in which at least one electrical component part 5 is arranged, for example a film capacitor. The housing 4 is filled, here in two layers 6a, 6b, with an electrically insulating potting compound 7, which forms an electrically insulating layer 8 covering the at least one electrical component part 5. The second component 3 comprises a printed circuit board 9 and at least one signal path 10 arranged on the printed circuit board 9, which can be integrated, for example, in an integrated circuit. The first and the second component 2, 3 are stacked one on top of another here and are mechanically connected via a shielding plate 11.

The shielding plate 11 protects the second component 3 from interference signals, on the one hand, such as electromagnetic radiation, of the first component 2 and moreover carries the second component 3. The shielding plate 11 is designed as a profiled plate 12. A thickness of the metallic profiled plate 12 is, for example, in the range of 0.4 mm to 1 mm. The shielding function is assumed by the material of the shielding plate 11, wherein the shielding plate 11 in particular completely covers the at least one first component part 5. The support function is assumed by a raised area 13 of the profiled plate 12, which comprises at least one raised bead 14. An upper side 15 of the raised bead 14 forms a support surface for the printed circuit board 9 here, on which adhesive points for firmly adhesively bonding the printed circuit board 9 on the shielding plate 11, and thus for mechanically connecting the second component 3 to the shielding plate 11, can be applied. The raised beads 14 are formed by forming, in particular deep-drawing. Because the printed circuit board 9 is only arranged on the profiled plate 12 in the area of the raised beads 14, the free oscillation length is limited and the printed circuit board 9 can be used in a larger area.

For the mechanical connection of the shielding plate 11 to the first component 2, a depressed area 16, which comprises at least one depressed bead 17, is mechanically connected to the electrically insulating layer 8. The at least one depressed bead 17 is arranged in some areas in the electrically insulating layer 8 here, for example in that the at least one depressed bead 17 is also embedded in the second layer 6b of the potting compound 7. In addition, the profiled plate 12 can be mechanically and therefore electrically connected to the metallic housing 4, for example via screws. Since the housing 4 is typically connected to a reference potential, for example a ground potential, of the motor vehicle, the profiled plate 12 is also connected to the reference potential. Since the profiled plate 12 is additionally fixed by the adhesive bond on the printed circuit board 9, the number of screw points can be kept low. Furthermore, it is possible to connect the reference potential of the profiled plate 12 to a ground terminal of the printed circuit board 9, for example by means of push-through installation and soldering of the integrated circuit with the printed circuit board 9. This is particularly advantageous if no access to the metal housing 4 is possible at the point of the profiled plate 12.

1.-10. (canceled)

11. An assembly for a power electronics module of a motor vehicle, comprising:
a first component having a first interference signal-emitting electrical component part and an electrically insulating layer covering the first electrical component part;
a second interference signal-sensitive component; and
a shielding plate, arranged between the first component and the second component, for shielding the second component from interference signals of the first component, wherein
the shielding plate is configured as a profiled plate having a raised area comprising at least one raised bead and a depressed area comprising at least one depressed bead,
the at least one depressed bead is mechanically connected to the electrically insulating layer of the first component for mechanically connecting the shielding plate to the first component, and
the at least one raised bead forms a support area for the second component, on which the second component abuts at least in some areas and is fastened.

12. The assembly according to claim 11, wherein
the first component comprises a housing open on one side, in which the first electrical component part is arranged and which is covered by the electrically insulating layer.

13. The assembly according to claim 12, wherein
the profiled plate is mechanically and electrically connected, via a screw connection, to the housing of the first component, the housing being a metallic housing.

14. The assembly according to claim 11, wherein
the electrically insulating layer is formed by a potting compound, using which the first electrical component part is at least partially covered and in which the at least one depressed bead is at least partially embedded.

15. The assembly according to claim 11, wherein
the depressed area comprises a lattice structure to improve the mechanical connection between the electrically insulating layer and the profiled plate.

16. The assembly according to claim 11, wherein
the second component is adhesively bonded on an upper side of the at least one raised bead, which forms the support area for the second component.

17. The assembly according to claim 11, wherein
the first component is an intermediate circuit capacitor for a power electronics module in the form of an inverter of the motor vehicle, and
the first electrical component part is an electrical capacitor.

18. The assembly according to claim 17, wherein the electrical capacitor is a film capacitor.

19. The assembly according to claim 11, wherein
the second component is a control unit for a power electronics module in the form of an inverter of the motor vehicle, and comprises at least one interference signal-sensitive signal path, which is arranged on a printed circuit board of the second component,
wherein the printed circuit board is fastened on the at least one raised bead.

20. The assembly according to claim 11, wherein
the profiled plate is a deep-drawn profiled plate, and
at least the at least one raised bead is formed as a hollow body open on one side in a direction of the electrically insulating layer.

21. A power electronics module for a motor vehicle comprising at least one assembly according to claim 11.
